(19) United States
(12) Patent Application Publication
(10) Pub. No.: US 2008/0164403 A1
(43) Pub. Date: Jul. 10, 2008

(54) Wide Dynamic Range Sensor

(75) Inventors: Ezra D. Hall, Richmond, VT (US); Anthony J. Perri, Jericho, VT (US)

Correspondence Address: DOWNS RACHLIN MARTIN PLLC, 199 MAIN ST, PO BO 190, BURLINGTON, VT, 05402-0190, US

(73) Assignee: International Business Machines Corporation, Armonk, NY (US)

(21) Appl. No.: 11/620,062

(22) Filed: Jan. 5, 2007

(51) Int. Cl. H01L 27/146

(52) U.S. Cl. 250/208.1; 257/E27.132

(57) ABSTRACT

A sensor and method for widening a dynamic range of sensor circuitry for sensing energy, such as light energy. The sensor circuitry includes a sensor and recharge circuitry for sharing additional charge with the sensor as needed during an integration period. Readout circuitry is provided to read out, after the integration period, the sense voltage remaining across the sensor and recharge information indicating whether the recharge circuitry shared charge with the sensor during the integration period. The sense voltage and recharge information read out of the sensor circuitry is used in a function to determine the total amount of energy sensed by the sensor during the integration period.

### FIELD OF THE INVENTION

The present invention generally relates to the field of sensors. In particular, the present invention is directed to a wide dynamic range sensor.

### BACKGROUND OF THE INVENTION

Various types of electronic-based sensors are used in a wide variety of applications. In many of these applications, it is desirable that the corresponding sensors have a wide dynamic range so that the sensors are able to achieve the desired results. For example, the human eye is capable of detecting light levels over a 1,000,000,000:1 absolute range, from fully adapted dark vision to fully adapted full sunlight/snow vision. At typical daylight lighting levels, the human eye can discern light contrast levels in a scene around 30,000:1. This allows the human eye to see both bright and dim objects together in a scene, as are normally present in the world around us.

Image sensors are often characterized as having a certain dynamic range. The dynamic range of an image sensor is commonly defined as the ratio of its largest non-saturating signal to the standard deviation of the noise under dark conditions. In other words, dynamic range refers to the range of incident light that can be accommodated by an image sensor in a single frame of sensor circuitry data, or single integration period. It is typically desirable to have an image sensor with a high dynamic range for imaging scenes that generate high dynamic range incident signals, such as indoor rooms with windows to the outside, outdoor scenes with mixed shadows and bright sunshine, night-time scenes combining artificial lighting and shadows, and many others. The dynamic range is limited on an upper end by the charge saturation level of the image sensor, and on a lower end by noise imposed limitations and/or quantization limits of the analog-to-digital converter used to produce the digital image. Image distortion may occur when the dynamic range of the image sensor is too small to accommodate the variations in light intensities of the image scene, e.g., by having a low saturation level.

Conventional digital and film cameras detect a limited dynamic range of light intensity levels. A wide dynamic range of light intensity levels in cameras is particularly desirable for the professional and high-end consumer, or “prosumer,” markets. However, conventional image sensors on consumer digital cameras are limited to a dynamic range of 400:1. Image sensors on high-end digital cameras for the professional and prosumer markets may achieve a dynamic range of approximately 2,000:1, which is still more than a factor of ten lower than the human eye. These dynamic range limited image sensors result in compromised images where exposure has to be set to either the dark or bright areas of an image, resulting in either fully saturated white regions or featureless black regions. Outdoor scenes are particularly sensitive to this phenomenon. Conventional digital cameras may have built-in histogram functions and sophisticated light-metering schemes to find the best compromise exposure for any given scene. However, these techniques and devices fall substantially short of the human eye's capabilities. Accordingly, it is highly desirable for a camera to have a wider and/or higher dynamic resolution to help address the limitations of the conventional systems.

### SUMMARY OF THE INVENTION

In one embodiment, the present disclosure is directed to an integrated circuit. The integrated circuit comprises sensor circuitry for sensing energy and having an integration period. The sensor circuitry includes a sensor precharged to a sense voltage and has a means for storing charge. The sensor is reactive to the energy by experiencing a decrease in the sense voltage. Recharge circuitry is in electrical communication with the sensor. The recharge circuitry is configured to share charge with the sensor during the integration period as a function of the sense voltage. Readout circuitry is configured to read out after the integration period the sense voltage and information indicating whether the recharge circuitry shared charge with the sensor during the integration period.

In another embodiment, the present disclosure is also directed to an integrated circuit. The integrated circuit chip comprises imaging sensor circuitry for sensing photons and having an integration period. The imaging sensor circuitry includes an array of sensors each for holding a sense voltage and each having a means for storing charge. Each sensor is reactive to the photons by experiencing a decrease in the sense voltage. A plurality of recharge circuitries are each in electrical communication with a corresponding respective one of the sensors and configured to share charge with the corresponding respective one of the sensors during the integration period as a function of the sense voltage. Readout circuitry is configured to read out after the integration period each of the sense voltages and information indicating whether each of the plurality of recharge circuitries triggered during the integration period.

In yet another embodiment, the present disclosure is directed to a method of increasing a dynamic range of a sensor during an integration period. The method comprises the steps of providing a sensor having a sense voltage and a means for storing charge. The sensor is responsive to energy by experiencing a decrease in the sense voltage during an integration period. The sense voltage is monitored during the integration period. If the sense voltage reaches a predetermined value during the integration period, additional charge is provided to the sensor during the integration period. At or after the end of the integration period, the sense voltage and information indicating whether the additional charge was provided to the sensor is read out.

In still another embodiment, the present disclosure is directed to a photosensor circuit for sensing light energy and having an integration period. The photosensor circuit comprises a photosensor having a capacitance and configured to be precharged to a sense voltage. The photosensor is reactive to the light energy by experiencing a decrease in the sense voltage. Recharge circuitry is in electrical communication with the photosensor. The recharge circuitry is configured to share charge with the photosensor, if needed, at least once during the integration period as a function of the sense voltage.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a high-level block diagram illustrating an integrated circuit incorporating a plurality of sensor circuitries each made in accordance with the present invention;

FIG. 2 is a schematic diagram illustrating a conventional sensor circuitry;

FIG. 3 is a schematic diagram illustrating a sensor circuitry made in accordance with an embodiment of the present invention; and

FIG. 4 is a schematic diagram illustrating a sensor circuitry made in accordance with another embodiment of the present invention.

### DETAILED DESCRIPTION

At a high level, the present disclosure is directed to methods and systems for widening and/or increasing a dynamic range of a sensor by connecting at least one switchable charge storing element to the sensor. The at least one switchable charge storing element provides an additional charge to the sensor for extending or increasing a charge collection capability of the sensor during an integration period when the sensor is exposed to levels of sensor input that would otherwise saturate the sensor. Illustrative embodiments of the methods and systems relating to this broad concept are described below.

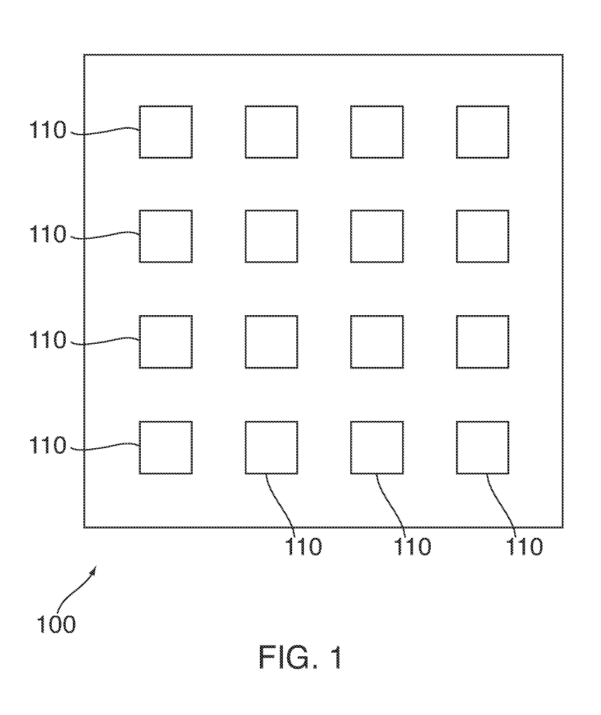

Referring now to illustrative embodiments, FIG. 1 illustrates an integrated circuit (IC) 100 that may be integrated into, but not limited to, an image capturing and/or processing device such as, but not limited to, a visible light camera, camcorder, and infrared camera. IC 100 may include, among other things, a plurality of sensor circuitries 110 arranged in an array for capturing an image. As described in more detail below, each sensor circuitry 110 may include a suitable sensor element, such as a photosensor, photo detector, or photoconversion device. IC 100 may be formed on a single IC chip (not shown) or, alternatively, on two or more IC chips, according to a particular design.

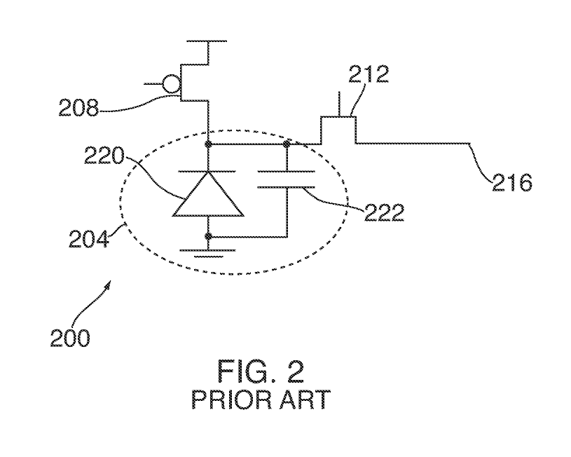

For the sake of comparing sensor circuitries 110 of the present disclosure to conventional sensor circuitry, FIG. 2 provides a schematic diagram of conventional sensor circuitry 200 for use in image capturing applications. In this example, conventional sensor circuitry 200 includes a photosensor 204, a reset transistor 208, a row enable transistor 212, and a shared column line 216. Photosensor 204 includes a photodiode 220, which will have its own intrinsic capacitance, and may contain additional capacitance in parallel through additional circuitry, both of which are lumped into capacitance 222 arranged in parallel. Reset transistor 208 resets photosensor 204 prior to an integration period, as explained below, in preparation for taking an image. Row enable transistor 212 provides a readout path for the voltage of photosensor 204 at the completion of the integration period.

During operation of circuitry 200, reset transistor 208 precharges photosensor 204 to a specific voltage. Reset transistor 208 then turns off. Sensor circuitry is now ready to start an integration period. During an integration period, e.g., the time a shutter such as an optical shutter (not shown) is open, photodiode 220 leaks or decays the stored charge in photosensor 204 according to a function proportional to the number of photons hitting photodiode 220 during the integration period. As long as the voltage on photosensor 204 does not decay below a noise floor or threshold of detection, photosensor 204 does not saturate during the integration period, the resulting voltage at the end of the integration period corresponds to the light level collected by the photodiode, with dark or black corresponding to a voltage near or at the specific pre-charge voltage, and bright or white (or blue, green, or red if the photosensor corresponds to a color pixel) corresponding to a voltage at or near zero, since photons cause the discharge of energy stored in the capacitance of photosensor 204. However, a dynamic range of light intensity level detection of conventional sensor circuitry 200 is limited.

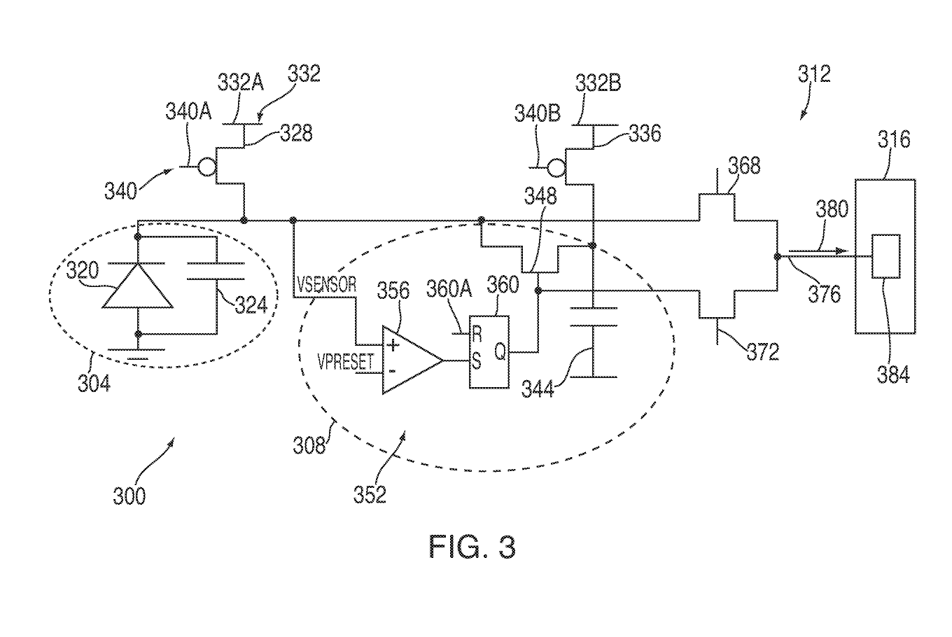

In contrast to conventional sensor circuitry 200 of FIG. 2, FIG. 3 illustrates sensor circuitry 300 made in accordance with one embodiment of the present invention that may be used for each of sensor circuitries 110 of FIG. 1. At a high level, sensor circuitry 300 includes, among other things, a photosensor 304 electrically connected to recharge circuitry 308 and in communication with readout circuitry 312.

During use, sensor circuitry 300 works as follows. Prior to an integration period, photosensor 304 and recharge circuitry 308 are each precharged to corresponding respective precharge levels through reset transistors 328 and 336 respectively. Latch 360 may be reset by an associated reset input 360A. During an integration period, photons (if any) are permitted to strike photosensor 304, thereby depleting a portion of the charge on the photosensor. If a sense voltage VSENSOR across photosensor 304 falls below a preset trigger voltage VPRESET during the integration period, e.g., some voltage above the saturation point of the photosensor, recharge circuitry 308 is triggered so as to share charge with the photosensor to allow the photosensor to continue responding to photons striking it, rather than simply saturating. Recharging photosensor 304 during the integration period effectively extends the dynamic range of the photosensor beyond its saturation point. If during a particular integration period, sense voltage VSENSOR across photosensor 304 does not fall below preset trigger voltage VPRESET, recharge circuitry 308 is not triggered and sensor circuitry 300 generally functions the same as conventional sensor circuitry, e.g., sensor circuitry 200 of FIG. 2. Readout circuitry 312 is configured to readout not only sense voltage VSENSOR across photosensor 304 at the end of each integration period, but also whether or not recharge circuitry 308 was triggered during that integration period. This information allows an output processor 316, e.g., image processing circuitry (which may be unique to sensor circuitry 300 or common to a plurality of sensor circuitries, e.g., all of sensor circuitries 110 of FIG. 1), to determine the level of light captured by photosensor 304 during each integration period. For example, if recharge circuitry 308 was not triggered during a particular integration period, the level of light captured by photosensor 304 is indicated by sense voltage VSENSOR across the photosenor at the end of the integration period. However, if recharged circuitry 308 was triggered during a certain integration period, the level of light captured by photosensor 304 is a function of not only sense voltage VSENSOR remaining across the photosensor at the end of the integration period, but also preset trigger voltage VPRESET at which the recharge circuitry was triggered to share charge with the photosensor. Details of exemplary recharge circuitry 308, readout circuitry 312, and other components of sensor circuitry 300 are described below.

Photosensor 304 may include a photodiode 320. Photodiode 320 may have its own intrinsic capacitance and may contain additional capacitance or any means for storing charge or energy, such as a charge storage device, in parallel through additional circuitry, both of which may be lumped into capacitance 324 electrically connected in parallel with one another as shown. It is noted that while sensor 304 is shown as a photosensor, those of ordinary skill in the art will readily appreciate that the sensor may be any sensor having an integration period and a dynamic range that can be increased with the addition of charge, while keeping within the scope and spirit of the present disclosure. A first reset transistor 328 may be electrically coupled between photosensor 304 and a first voltage source 332A for recharging the photosensor prior to each integration period. Similarly, a second reset transistor 336 may be electrically coupled between recharge circuitry 308 and a second voltage source 332B for recharging the recharge circuitry prior to each integration period. Each of first and second reset transistors 328, 336 may be controlled by a reset signal on reset lines 340A-B. Additionally, first voltage source 332A and second voltage source 332B may be different voltage sources or the same voltage source.

Recharge circuitry 308 may include, among other things, a charge storing device 344, e.g., a capacitor, for storing a recharging charge, a switch 348, e.g., a transistor, for connecting the storage device as needed to share charge with photosensor 304, and trigger circuitry 352, e.g., a comparator 356 connected to a latch 360, for controlling the switch as a function of sense voltage VSENSOR across photosensor 304 and preset trigger voltage VPRESET. Comparator 356 may include an operational amplifier, as illustrated in FIG. 3, or any device that compares two voltages capable of determining the level of sense voltage VSENSOR. Latch 360 is illustrated as an SR latch in FIG. 3, but may include any other type of latch or data storage device. Charge storing device 344 may include, but is not limited to, a capacitor or any other energy storage device. As those skilled in the art will readily appreciate, each of charge storing device 344, switch 348 and trigger circuitry 352 may be made of other electronic devices.

Readout circuitry 312 may include, among other things, a first row enable transistor 368 for reading out sense voltage VSENSOR across photodiode 320, a second row enable transistor 372 for separately reading out the state of latch 360, and a common column line 376 connected to the first and second row enable transistors as shown. In an array containing a plurality of sensor circuitries (e.g., a pixel array), first and second row enable transistors 368, 372 may each be associated with a row of addresses of the array. First and second row enable transistors 368, 372 may each turn on at separate times to activate all the columns of the associated row to drive a sensor circuitry readout result 380 from each respective common column line 376, in the array. Each column address may be used to select the desired output of common column line 376 to be driven out of the circuit, e.g., into an analog-to-digital converter ADC 384.

During operation, prior to an integration period, reset transistor 328 is turned on to pre-charge photosensor 304, and reset transistor 336 is turned on to precharge recharge circuit 304 to specific precharge voltage levels. Latch 360 may be reset by reset input 360A. Reset transistors 328 and 336 then turn off. Photosensor 304 is now ready to start an integration period. During an integration period, e.g., during the time a mechanical, optical, and/or electronic shutter is open, sensor voltage VSENSOR across photodiode 320 diminishes from its precharge level according to a function proportional to the number of photons (if any) striking the photodiode during the integration period. As sensor voltage VSENSOR diminishes during the integration period, comparator 356 compares sensor voltage VSENSOR with preset trigger voltage VPRESET, which may be a default, pre-defined, or user-defined voltage. When sensor voltage VSENSOR across photodiode 320 reaches preset trigger voltage VPRESET during the integration, comparator 356 sets latch 360 to close switch 348, thereby allowing charge storing device 344 to share charge with photosensor 304 during the integration period. As the integration period continues, sensor voltage VSENSOR across the now recharged photosensor 304 may continue to diminish as additional photons strike photodiode 320. At the end of the integration period, e.g., when the mechanical, optical, and/or electronic shutters close in the case of an electromagnetic energy or particle sensor, a certain level of sensor voltage VSENSOR remains for readout. As seen, the additional charge provided by charge storing device 344 effectively increases the dynamic range of sensor circuitry 300, thereby allowing the sensor circuitry to capture levels of light beyond the saturation point of photosensor 304 in the absence of recharge circuitry 308.

During a readout of sensor circuitry 300, sensor voltage VSENSOR is read out by readout circuitry 312, as is the open/closed state of first switch 348, as indicated by the output of latch 360. The state of first switch 348 is used as an input to a function which is applied to measured readout result 380 of photosensor voltage to compensate or adjust for the additional charge introduced by connecting additional capacitance element 344. For example, if an additional capacitive charge was provided by capacitive element 344, readout result 380 of photosensor voltage of sensor circuitry 300 would be adjusted by the function for the addition of capacitive element 344, to obtain the final readout value. After completion of sensor circuitry 300 readout, first reset switch 328 and second reset switch 336 may reset photosensor 304 and recharge circuitry 308, respectively, and reset signal 360A may reset latch 360, in preparation for taking another image. Since the state of switch 348 is also available for sensor circuitry 300, the specific switch voltage levels, as determined by comparator 308, on a per sensor circuitry basis, do not necessarily have to be precise.

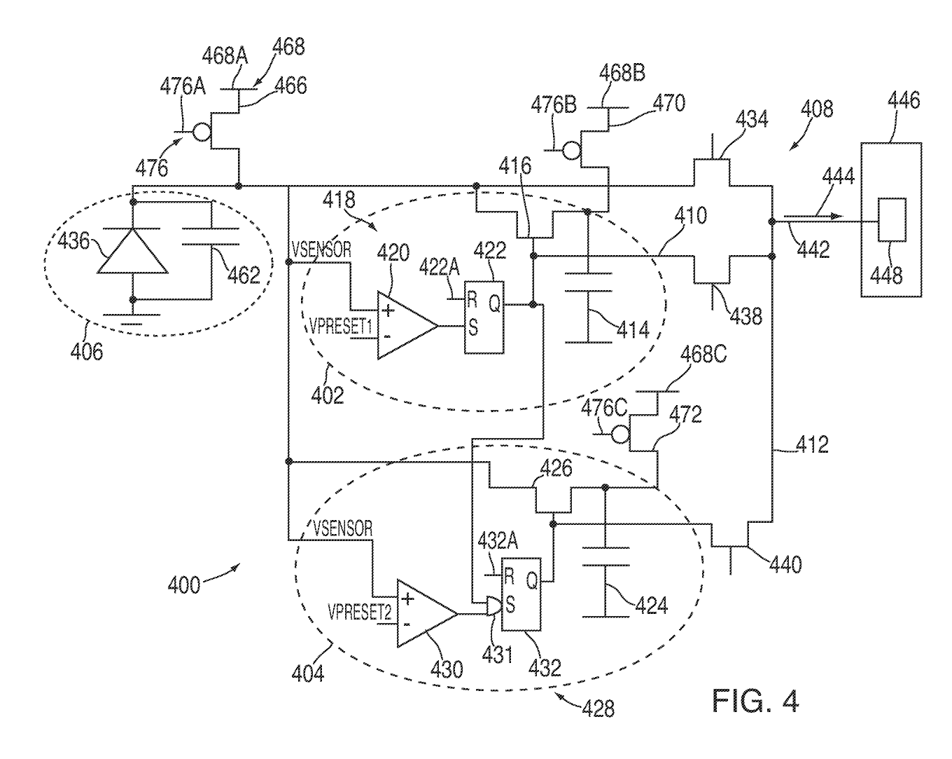

FIG. 4 illustrates a multi-level-recharge sensor circuitry 400 according to another embodiment of the present disclosure. Sensor circuitry 400 operates in a substantially similar manner to sensor circuitry 300 and may include the same or similar components and may be used for each sensor circuitry 110 of FIG. 1. However, instead of the single recharge circuitry 308 of FIG. 3, sensor circuitry 400 of FIG. 4 includes, among other things, recharge circuitry that includes first recharge sub-circuit 402 and a second recharge sub-circuit 404. It will be understood that while two recharge sub-circuits 402, 404 are shown, three or more recharge sub-circuits may be used depending upon a particular design. Those skilled in the art will understand how to implement three or more recharge circuitries using the concepts described below relative to first and second recharge sub-circuits 402, 404 shown.

Multi-level-recharge sensor circuitry 400 includes, among other things, a sensor 406 electrically connected to sensor readout circuitry 408 and to first and second recharge sub-circuits 402, 404, which may be electrically coupled in parallel to the sensor as shown. Each of first and second recharge sub-circuits 402, 404 may be electrically connected to, respectively, first switch-state readout circuitry 410 and second switch-state readout circuitry 412. It is noted that while sensor 406 may be a photosensor similar to photosensor 304 of FIG. 3, those of ordinary skill in the art will readily appreciate that the sensor may be any sensor having an integration period and a dynamic range that can be increased with the addition of charge, while keeping within the scope and spirit of the present disclosure.

First and second recharge sub-circuits 402, 404 may include substantially similar components and devices as one another. For example, first recharge sub-circuit 402 shown includes a first charge storing device 414, e.g., a capacitor, for storing a recharging charge. First recharge sub-circuit 402 shown also includes a first switch 416, e.g., a transistor, for connecting first charge storing device 414 as needed to share charge with sensor 406. In addition, first recharge sub-circuit 402 shown includes first trigger circuitry 418 that may include, e.g., a first comparator 420 connected to a first latch 422, for controlling first switch 416 as a function of a voltage VSENSOR across sensor 406 and a first preset trigger voltage VPRESET1. First comparator 420 may include an operational amplifier, as illustrated in FIG. 4, or any device that compares two voltages or can otherwise determine the level of sensor voltage VSENSOR. First latch 422 is illustrated as an SR latch in FIG. 4, but may include any other type of latch or any other type of device capable of generating a trigger signal for controlling the state of switch 416.

Likewise, second recharge sub-circuit 404 may include similar components and devices as first recharge sub-circuit 402, such as a second charge storing device 424, a second switch 426, and a second trigger circuitry 428, e.g., a second comparator 430 connected to a second latch 432, for controlling the second switch as a function of sensor voltage VSENSOR across sensor 406 and a second preset trigger voltage VPRESET2. In this embodiment, second latch 432 is responsive to an output of an AND-gate 431 that operates on the output of first latch 422 and the output of second comparator 430 to ensure that switch 426 is triggered only after first switch 416 has been triggered and, therefore, only after sensor 406 has been recharged once by first recharge sub-circuit 402. As those skilled in the art will readily appreciate, each of charge storing devices 414, 424, switches 416, 426, and trigger circuitries 418, 428 may be made of electronic devices other than the devices shown.

Readout circuitry 408 may include, among other things, a first row-enable transistor 434 for reading out sensor voltage VSENSOR across sensor 406. Similarly, first and second switch-state readout circuitries may each include, respectively, a second row-enable transistor 438 for separately reading out the state of first latch 422 and a third row-enable transistor 440 for separately reading out the state of second latch 432. First, second, and third row-enable transistors 434, 438, 440 may share a common column line 442 so as to provide sensor circuitry readout result 444, at separate times. In an array containing a plurality of sensor circuitries each similar to sensor circuitry 400 (e.g., a pixel array), first, second, and third row-enable transistors 434, 438, 440 may each be associated with a row of addresses of the array. First, second, and third row enable transistors 434,438, 440 may each turn on separately to activate all the columns of the associated row to drive sensor circuitry readout result 444 into common column line 442. Each column address may be used to select the desired output of common column line 442 to be driven out of the circuit into an output processor 446, e.g., into an analog-to-digital converter (ADC) 448.

The use of sensory circuitry 400 of the illustrative embodiment of FIG. 4 may be as follows. Prior to an integration period, sensor 406, first recharge sub-circuit 402, and second recharge circuitry 404 are each precharged to corresponding respective precharge levels. Latch 422 and latch 426 are reset by means of their reset inputs 422A and 422B, respectively. During the integration period, energy, (if any) such as photons or light, may strike sensor 406, thereby depleting a portion of the charge on the sensor. If sensor voltage VSENSOR across sensor 406 falls below first preset trigger voltage VPRESET1, e.g., some voltage above the saturation point of the sensor, during the integration period, first trigger circuitry 418 triggers first recharge sub-circuit 402 so as to share charge stored in capacitor 414 with the sensor 406 to allow the sensor to continue responding to energy striking it, rather than simply saturating. Sharing charge with sensor 406 during the integration period effectively extends or widens the dynamic range of the sensor beyond its saturation point without recharge circuitry 402. If during a particular integration period, sense voltage VSENSOR across sensor 406 does not fall below first preset trigger voltage VPRESET1 and first recharge sub-circuit 402 is not triggered, sensor circuitry 400 generally functions the same as conventional sensor circuitry, e.g., sensor circuitry 200 of FIG. 2.

If, during the same integration period and after recharge circuit 402 has been triggered as stored in the state of latch 422, sense voltage VSENSOR again falls below some preset trigger voltage level, e.g., second preset trigger voltage VPRESET2, second trigger circuitry 428 will close second switch 426 and, thereby, again share additional charge with the sensor. This allows sensor 406 to continue responding to energy striking it, rather than saturating as would be the case without recharge circuitry 404. It can be clearly seen that this second charge sharing with sensor 406 by second recharge sub-circuit 404 during the integration period effectively further extends or widens the dynamic range of the sensor even further than when the sensor is solely sharing charge with the first recharge sub-circuit 402.

It is noted that first and second preset trigger voltages VPRESET1, VPRESET2 may be the same as one another in some embodiments and may be different from one another in other embodiments. The choices of first and second preset trigger voltages VPRESET1, VPRESET2 may depend on a number of factors, such as the maximum intensity to be sensed by sensor 406 during the worst-case integration period, the sensitivity and dynamic range of the sensor standing alone, and the desired level of performance of the device incorporating sensor circuitry 400, among others. These factors can also be considered in determining how many recharge sub-circuits to provide, from one (such as in FIG. 3), two (such as in FIG. 4) or three or more. If three or more recharge sub-circuits are provided, they may be organized into a chain much like first and second sub-circuits 402, 404 shown. Those of ordinary skill in the art will readily appreciate how to increase the number of recharge sub-circuits beyond two so that any later-stage sub-circuit is not triggered until the immediately prior sub-circuit has been triggered. For example, this can be done using AND-gates similar to AND-gate 431 that operates on signals from each of the current level and the immediately preceding level.

In this illustrative embodiment of FIG. 4, sensor 406 includes a diode 436, which may have its own intrinsic capacitance and may contain additional capacitance or any means for storing charge, such as a capacitor or charge storage device, in parallel through additional circuitry, both of which may be lumped into capacitance 462 electrically connected in parallel with one another as shown. A first reset switch 466, e.g., a transistor, may be electrically coupled between sensor 406 and a first voltage source 468A for recharging the sensor prior to each integration period. Similarly, a second reset switch 470 may be electrically coupled between first recharge sub-circuit 402 and a second voltage source 468B for recharging the first recharge sub-circuit prior to each integration period. Additionally, a third reset switch 472 may be electrically coupled between second recharge sub-circuit 404 and a third voltage source 468C for recharging the second recharge sub-circuit prior to each integration period. Each of first, second, and third reset switches 466, 470, 472 may be controlled by a reset signal on a reset line 476, e.g., 476A, 476B, and 476C, respectively. The reset inputs of latch 422 and latch 432 may also be controlled by reset signals 422A and 432A respectively. Additionally, first voltage source 468A, second voltage source 468B, and third voltage source 468C may be different voltage sources, the same voltage source, and any combinations thereof.

Describing the operation of sensor circuitry 400 in a bit more detail using the additional elements introduced in the immediately preceding paragraph, during operation and prior to the integration period, reset switch 466 precharges sensor 406 to a specific precharge voltage, reset switch 470 precharges capacitor 414 to a specific precharge voltage, and reset switch 472 precharges capacitor 424 to a specific precharge voltage. Reset switches 466, 470, and 472 then turn off. Latch 422 and latch 426 may be reset by reset inputs 422A and 432A respectively. Sensor 406 is now ready to start an integration period. During an integration period, e.g., during the time a mechanical, optical, and/or electronic shutter is open in the case of an electromagnetic energy or particle sensor, sense voltage VSENSOR across diode 436 may diminish from its precharge level according to a function proportional to the amount of energy striking the diode during the integration period. As sense voltage VSENSOR diminishes during the integration period, first comparator 420 compares sense voltage VSENSOR with first preset trigger voltage VPRESET1, which may be a default, pre-defined, or user-defined voltage. When sense voltage VSENSOR across diode 436 reaches or goes below first trigger voltage VPRESET1 during the integration period, first comparator 420 sets latch 422 to close switch 416, thereby allowing first charge storing device 414 to share charge with sensor 406 during the integration period. As the integration period continues, sense voltage VSENSOR across the now recharged sensor 406 may continue to diminish as additional energy, such as photons, strikes diode 436.

As sense voltage VSENSOR continues to diminish during the integration period, second comparator 430 may compare sense voltage VSENSOR with second preset trigger voltage VPRESET2, which may be a default, pre-defined, or user-defined voltage that is the same as or different from first preset trigger voltage VPRESET1. When sense voltage VSENSOR across diode 436 reaches or goes below second trigger voltage VPRESET2 during the integration period, second comparator 430 sets second latch 432 to close second switch 426, thereby allowing second charge storing device 424 to share charge with sensor 406 during the integration period. As the integration period continues, sense voltage VSENSOR across the now twice recharged sensor 406 may continue to diminish as additional energy strikes diode 436. At the end of the integration period, e.g., when the mechanical, optical, and/or electronic shutters close in the case of an electromagnetic energy or particle sensor, a certain level of sense voltage VSENSOR remains for readout. As seen, the additional charge provided by each of first and second charge storing devices 414, 424 effectively and incrementally increases or widens the dynamic range of sensor circuitry 400, thereby allowing the sensor circuitry to capture levels of light or energy beyond the saturation point of diode 436 in the absence of first and second recharge circuitries 402, 404.

During a readout of sensor circuitry 400, sense voltage VSENSOR and the states of first and second latches 422, 432, which indicate whether or not the corresponding recharge sub-circuit 402, 404 was triggered to recharge sensor 406, are read out by readout circuitry 408 at separate times. The states of first and second switches 416, 426 may be used as input to a function applied to measured readout result 444 to compensate or adjust sense voltage VSENSOR for the additional capacitance, if any, provided by each of first and second charge storing devices 414, 424 during the integration period. Since the states of first switch 416 and second switch 428 may also be available for sensor circuitry 400, the specific switch voltage levels on a per sensor circuitry basis do not necessarily have to be precise.

After completion of sensor circuitry 400 readout, first reset switch 466, second reset switch 470, and third reset switch 472 may reset sensor 406, first recharge circuitry 402, and second recharge circuitry 404, respectively, and latch 422 and latch 432 may be reset by reset signals 422A and 432A, respectively, in preparation for capturing energy during another integration period, e.g., taking another image.

Exemplary embodiments have been disclosed above and illustrated in the accompanying drawings. It will be understand by those skilled in the art that various changes, omissions and additions may be made to that which is specifically disclosed herein without departing from the spirit and scope on the invention.

What is claimed is:

1. An integrated circuit, comprising:
sensor circuitry for sensing energy and having an integration period, said sensor circuitry including:
a sensor precharged to a sense voltage and having a means for storing charge, said sensor being reactive to said energy by experiencing a decrease in said sense voltage;
recharge circuitry in electrical communication with said sensor, said recharge circuitry configured to share charge with said sensor during said integration period as a function of said sense voltage; and
readout circuitry configured to read out after said integration period said sense voltage and information indicating whether said recharge circuitry shared charge with said sensor during said integration period.

2. The integrated circuit according to claim 1, wherein said sensor comprises a photosensor.

3. The integrated circuit according to claim 1, wherein said sensor comprises an infrared sensor.

4. The integrated circuit according to claim 1, wherein said recharge circuitry generates a trigger signal as a function of a preset trigger voltage and said sense voltage.

5. The integrated circuit according to claim 1, wherein said recharge circuitry comprises:
a charge storing device;
a switch coupled between said charge storing device and said sensor; and
trigger circuitry in operative communication with said switch, said trigger circuitry configured to control said switch as a function of said sense voltage.

6. The integrated circuit according to claim 5, wherein said trigger circuitry comprises:
a voltage reference circuit generating a preset trigger voltage; and
a comparator comparing said sense voltage and said preset trigger voltage so as to generate said trigger signal that triggers said switch.

7. The integrated circuit according to claim 1, wherein said recharge circuitry comprises at least two charge storing devices, said recharge circuitry configured to share charge with said sensor sequentially during said integration period using said at least two charge storing devices.

8. The integrated circuit according to claim 1, wherein said readout circuitry comprises:
sensor readout circuitry in electrical communication with said sensor, said sensor readout circuit configured to generate a sensor readout signal corresponding to said sense voltage at the end of said integration period; and
recharge readout circuitry in electrical communication with said recharge circuitry, said recharge readout circuitry configured to generate a recharge readout signal indicating whether said recharge circuitry triggered during said integration period.

9. The integrated circuit according to claim 8, further comprising output circuitry that outputs for said integration period a sensed-level signal as a function of said sensor readout signal and said recharge readout signal.

10. The integrated circuit according to claim 9, wherein said sensor is a photosensor and said sensed-level signal corresponds to a light level sensed by said sensor circuitry.

11. The integrated circuit according to claim 1, wherein said sensor circuitry further comprises:
a first reset circuit in electrical communication with said sensor, said first reset circuit configured to reset said sensor prior to said integration period; and
a second reset circuit in electrical communication with said recharge circuitry, said second reset circuit configured to reset said recharge circuitry prior to said integration period.

12. An integrated circuit, comprising:
imaging sensor circuitry for sensing photons and having an integration period, said imaging sensor circuitry including:
an array of sensors each for holding a sense voltage and each having a means for storing charge, each sensor being reactive to said photons by experiencing a decrease in said sense voltage;
a plurality of recharge circuitries each in electrical communication with a corresponding respective one of said sensors and configured to share charge with said corresponding respective one of said sensors during said integration period as a function of said sense voltage; and
readout circuitry configured to read out after said integration period each said sense voltage and information indicating whether each of said plurality of recharge circuitries triggered during said integration period.

13. The integrated circuit according to claim 12, wherein said array comprises an array of photosensors.

14. The integrated circuit according to claim 12, wherein said array comprises an array of infrared sensors.

15. The integrated circuit according to claim 12, wherein each of said plurality of recharge circuitries generates a trigger signal as a function of a preset trigger voltage and said sense voltage.

16. The integrated circuit according to claim 12, wherein each of said recharge circuitries comprises:
a charge storing device;
a switch coupled between said charge storing device and said sensor; and
trigger circuitry in operative communication with said switch, said trigger circuitry configured to control said switch as a function of said sense voltage.

17. The integrated circuit according to claim 16, wherein said trigger circuitry comprises:
a voltage reference circuit generating a preset trigger voltage; and
a comparator comparing said sense voltage and said preset trigger voltage so as to generate said trigger signal that triggers said switch.

18. The integrated circuit according to claim 12, wherein each of said recharge circuitries comprises at least two charge storing devices and is configured to share charge with a corresponding respective sensor in said array of sensors sequentially during said integration period using said at least two charge storing devices.

19. The integrated circuit according to claim 12, wherein said readout circuitry comprises:
sensor readout circuitry in electrical communication with each sensor in said array of sensors, said sensor readout circuit configured to generate sensor readout signals each corresponding to a respective said sense voltage at the end of said integration period; and
recharge readout circuitry in electrical communication with each of said plurality of recharge circuitries, said recharge readout circuit configured to generate recharge readout signals each indicating whether a corresponding respective one of said plurality of recharge circuitries triggered during said integration period.

20. The integrated circuit according to claim 19, further comprising output circuitry that outputs for said integration period a sensed-level signal corresponding to each sensor of said array of sensors, said sensed-level signal being a function of a corresponding respective said sensor readout signal and a corresponding respective said recharge readout signal.

21. The integrated circuit according to claim 20, wherein each sensor in said array of sensors is a photosensor and each said sensed-level signal corresponds to a light level sensed via a corresponding respective sensor of said array of sensors.

22. The integrated circuit according to claim 12, wherein said sensor circuitry further comprises:
a first reset circuit in electrical communication with said sensor, said first reset circuit configured to reset said sensor prior to said integration period; and
a second reset circuit in electrical communication with said recharge circuitry, said second reset circuit configured to reset said recharge circuitry prior to said integration period.

23. A method of increasing a dynamic range of a sensor during an integration period, comprising:
providing a sensor having a sense voltage and a means for storing charge, said sensor responsive to energy by experiencing a decrease in said sense voltage during an integration period;
monitoring said sense voltage during said integration period;
if said sense voltage reaches a predetermined value during said integration period, providing additional charge to said sensor during said integration period; and
reading out, at or after the end of said integration period, said sense voltage and information indicating whether said additional charge was provided to said sensor.

24. The method according to claim 23, wherein the step of monitoring said sense voltage includes comparing said sense voltage to a preset trigger voltage and the step of providing additional charge includes providing said additional charge to said sensor when said sense voltage reaches or goes below said preset trigger voltage.

25. The method according to claim 23, wherein the step of providing a sensor includes providing either a photosensor or an infrared sensor.

26. The method according to claim 23, wherein the step of providing additional charge to said sensor occurs at least two times sequentially.

27. The method according to claim 23, further comprising the step of generating a sensed energy level signal as a function of said sensed voltage and said information each read out at or after the end of said integration period.

28. A photosensor circuit for sensing light energy and having an integration period, the photosensor circuit comprising:
a photosensor having a capacitance and configured to be precharged to a sense voltage, said photosensor being reactive to the light energy by experiencing a decrease in said sense voltage; and
recharge circuitry in electrical communication with said photosensor, said recharge circuitry configured to share charge with said photosensor, if needed, at least once during said integration period as a function of said sense voltage.

29. The photosensor circuit according to claim 28, wherein said recharge circuitry is configured to share charge with said photodiode at least twice, if needed, during said integration period.

30. The photosensor circuit according to claim 28, wherein said recharge circuitry comprises:
trigger circuitry for comparing said sense voltage with a preset trigger voltage;
a switch connected to said trigger circuitry; and
a charge storing device connected to said switch;
wherein said trigger circuitry generates a trigger signal when said sense voltage is substantially equal to said preset trigger voltage to close said switch to activate said charge storing device for providing an additional capacitive charge to said photodiode during said integration period.
